(19) United States
(12) Patent Application Publication
(10) Pub. No.: US 2004/0087137 A1
(43) Pub. Date: May 6, 2004

(54) Method of manufacturing interconnection structure applied to semiconductor device

(75) Inventors: Hiroki Takewaka, Hyogo (JP); Takashi Yamashita, Hyogo (JP); Takeshi Masamitsu, Hyogo (JP)

Correspondence Address: LEYDIG VOIT & MAYER, LTD, 700 THIRTEENTH ST. NW, SUITE 300, WASHINGTON, DC, 20005-3960, US

(73) Assignees: Mitsubishi Denki Kabushiki Kaisha, Tokyo (JP); Ryoden Semiconductor System Engineering Corporation, Itami-shi (JP)

(21) Appl. No.: 10/406,184

(22) Filed: Apr. 4, 2003

(30) Foreign Application Priority Data
Oct. 22, 2002 (JP) 2002-307324

(51) Int. Cl. H01L 21/4763

(52) U.S. Cl. 438/633

(57) ABSTRACT

A barrier metal layer constituted of a TiN layer and a Ti layer is formed on a surface of an interlayer insulating film and on an inside surface of an interconnection recess formed in the interlayer insulating film while a substrate is maintained at a temperature of at least 200° C. and lower than 300° C. The interconnection recess is filled with a conductive layer and an extra part of the conductive layer that is deposited on the interlayer insulating film is removed through such a polishing process to form a conductive plug. In the process of forming the barrier metal layer, as the substrate is maintained at the temperature, the residual stress in the deposited barrier metal layer can be reduced. Accordingly, it is achieved to suppress peeling which occurs at the interface between the barrier metal layer and the interlayer insulating film in the polishing process.

### BACKGROUND OF THE INVENTION

1. Field of the Invention

The present invention relates to a method of manufacturing an interconnection structure applied to a semiconductor device, and more particularly, to a method of manufacturing an interconnection structure applied to a semiconductor device that can suppress peeling of a conductive layer in such a polishing process as chemical mechanical polishing (CMP).

2. Description of the Background Art

With the recent scaling down in size of semiconductor integrated circuits, there have been increasing circuits having conductive plugs and damascene interconnections formed thereon. The plugs and damascene interconnections are formed first by making a connection hole and an interconnection trench in an interlayer insulating film. Then, a barrier metal layer constituted of a TiN/Ti layer is formed on the inside surface of the recessed part of the interconnection (interconnection recess) and on the surface of the interlayer insulating film (see Japanese Patent Laying-Open No. 10-70091). Further, such a conductive layer as tungsten film is formed thereon by CVD (Chemical Vapor Deposition) and then any extra part of the conductive layer is polished to be removed by CMP.

The scaling down of the integrated-circuit substrate requires satisfactory recess-filling of the conductive layer for the interconnection recess. In order to accomplish this, the barrier metal layer, i.e., TiN/Ti film must be improved in coverage, and this coverage is improved by employing directional sputtering. In particular, according to a method which is employed in these years, the directivity is improved by applying a bias to ionized sputtering particles.

As shown in FIG. 8, however, a conductive layer 104 on the TiN/Ti film, i.e., a barrier metal layer 103, formed by the above-discussed sputtering method could peel off at the interface between itself and an interlayer insulating film 102 in a CMP process using slurry 105 and an abrasive cloth 106. Such peeling occurring at those locations indicated respectively by A and B in FIG. 8 results in local over-polishing of interlayer insulating film 102 at these locations in a subsequent CMP process. Then, problems occur that are deterioration in the surface planarity, exposure of an underlying interconnection, and scratches of the wafer surface by peeled-off fragments of the interlayer insulating film.

### SUMMARY OF THE INVENTION

One object of the present invention is to provide a method of manufacturing an interconnection structure applied to a semiconductor device that can suppress peeling-off which occurs at the interface between a barrier metal layer and an interlayer insulating film in such a polishing process as CMP.

According to one aspect of the present invention, a method of manufacturing an interconnection structure applied to a semiconductor device including an interlayer insulating film formed on a substrate as well as a conductive plug and a damascene interconnection formed in the interlayer insulating film includes the steps of forming a barrier metal layer constituted of a Ti layer and a TiN layer on a surface of the interlayer insulating film and on an inside surface of an interconnection recess formed in the interlayer insulating film, forming a conductive layer to fill the interconnection recess, and polishing to remove a deposited extra part of the conductive layer. The substrate has a temperature maintained to be at least 200° C. and lower than 300° C. for forming the TiN layer in the step of forming the barrier metal layer.

According to another aspect of the present invention, a method of manufacturing an interconnection structure applied to a semiconductor device including an interlayer insulating film formed on a substrate as well as a conductive plug and a damascene interconnection formed in the interlayer insulating film includes the steps of forming a barrier metal layer on a surface of the interlayer insulating film and on an inside surface of an interconnection recess formed in the interlayer insulating film, forming a conductive layer to fill the interconnection recess, and polishing to remove a deposited extra part of the conductive layer. Bias sputtering is carried out in the step of forming the barrier metal layer with bias power in the bias sputtering being at most 100 W.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of an interconnection structure of a semiconductor device manufactured according to a first embodiment of the present invention.

FIGS. 2 to 5 are cross sectional views respectively showing first to fourth steps of a process of forming a conductive plug in an interlayer insulating film according to the first embodiment of the present invention.

FIG. 6 schematically shows a sputtering apparatus according to first and second embodiments of the present invention.

FIG. 7 is a cross sectional view showing a part of a process of forming a conductive plug in an interlayer insulating film according to the second embodiment of the present invention.

FIG. 8 is a cross sectional view showing a step of a conventional method of manufacturing an interconnection structure applied to a semiconductor device.

### DESCRIPTION OF THE PREFERRED EMBODIMENTS

With reference to the drawings, description is now given below of a method of manufacturing an interconnection structure applied to a semiconductor device according to embodiments of the present invention. It is noted that “interconnection recess” herein refers to such a connection hole as a contact hole and a via hole for a conductive plug filling the hole or refers to an interconnection trench for forming a damascene interconnection therein, the connection hole and the interconnection trench being formed in an interlayer insulating film.

First Embodiment

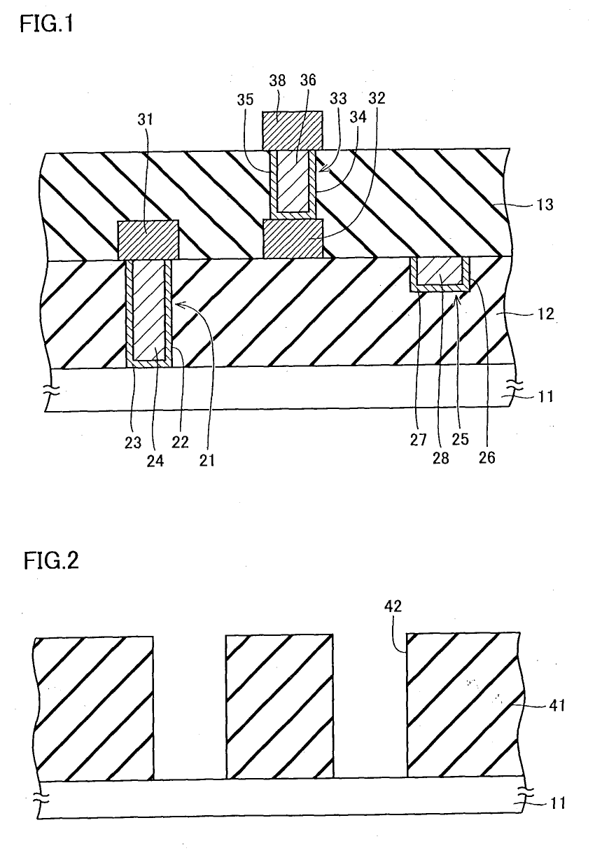

Referring to FIG. 1, an interconnection structure of a semiconductor device is described below.

On a substrate 11 formed of Si, a first interlayer insulating film 12 formed of SiO is formed. In this first interlayer insulating film 12, a first conductive plug 21 and a damascene interconnection 25 are provided. The first conductive plug 21 has a barrier metal layer 23 formed on the inside surface of a via hole 22 which is an interconnection recess, and via hole 22 is filled with a conductive layer 24. Damascene interconnection 25 has a barrier metal layer 27 on the inside surface of an interconnection trench 26 which is also an interconnection recess, and this interconnection trench 26 is filled with a conductive layer 28. These barrier metal layers 23 and 27 are formed of a TiN layer and a Ti layer (hereinafter referred to as TiN/Ti layer), and conductive layers 24 and 28 are formed of tungsten or aluminum, for example.

On the first interlayer insulating film 12, a second interlayer insulating film 13 formed of SiO is formed. In the second interlayer insulating film 13, a first interconnection layer 31 and a second interconnection layer 32 are provided, and the first interconnection layer 31 is connected to the first conductive plug 21. Further, a second conductive plug 33 is provided to connect to the second interconnection layer 32, and a third interconnection layer 38 is provided to connect to the second conductive plug 33. The second conductive plug 33 has a barrier metal layer 35 on the inside surface of a contact hole 34 which is an interconnection recess, and the interconnection recess is filled with a conductive layer 36.

Referring to FIGS. 2 to 5, a method of manufacturing an interconnection structure applied to a semiconductor device is described. Here, a method of manufacturing such a conductive plug as the first conductive plug 21 that is described above in connection with the interconnection structure is specifically described.

Referring to FIG. 2, on the upper surface of substrate 11 formed of Si, an interlayer insulating film 41 formed of SiO is formed. Then, a resist is applied onto interlayer insulating film 41 and the resist is patterned to form a resist pattern (not shown). The resist pattern is used as a mask for dry etching, and thus a via hole 42 which is an interconnection recess is produced.

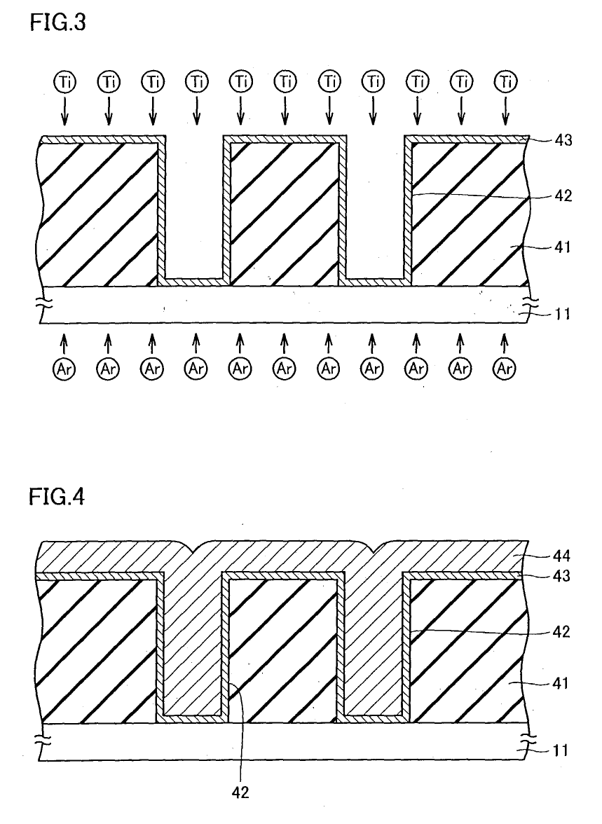

Referring to FIG. 3, a barrier metal layer 43 is formed on the surface of interlayer insulating film 41 and on the inside surface of via hole 42 by directional bias sputtering (process of forming a barrier metal layer). Barrier metal layer 43 is constituted of a TiN/Ti layer. In this process, argon gas at a predetermined temperature is blown onto the lower surface of substrate 11 to heat substrate 11 to a temperature of at least 200° C. and lower than 300° C. The temperature of this argon gas is set at approximately 200° C.-300° C. This temperature is maintained while the Ti layer is deposited by directional bias sputtering. Further, the above-mentioned temperature is still maintained while the TiN layer is deposited by directional bias sputtering.

Referring to FIG. 4, a conductive layer 44 made of aluminum is formed within via hole 42 (process of forming a conductive layer). Conductive layer 44 is produced by CVD to be deposited not only within via hole 42 but also on the surface of interlayer insulating film 41.

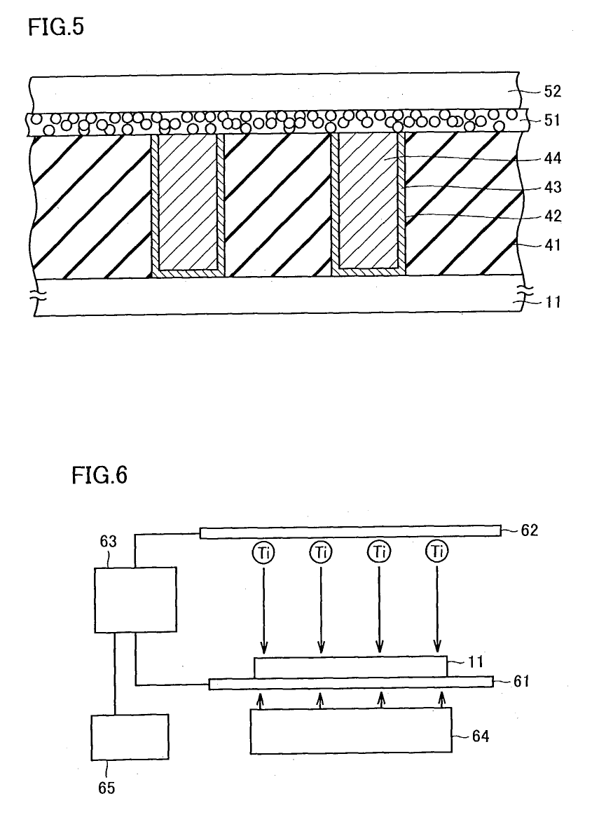

Referring to FIG. 5, by means of CMP, an extra part of conductive layer 44 that is deposited on interlayer insulating film 41 is polished and accordingly removed (polishing process). In the CMP, slurry 51 is supplied onto the surface of conductive layer 44 and friction is applied in the horizontal direction by an abrasive cloth 52. Simultaneously, a part of barrier metal layer 43 that is deposited on the surface of interlayer insulating film 41 is also removed. After the CMP process, respective surfaces of interlayer insulating film 41 and conductive layer 44 for a conductive plug are exposed.

Regarding the first embodiment, a sputtering apparatus used for the directional bias sputtering is described. As shown in FIG. 6, the sputtering apparatus includes a positive electrode 61 contacting substrate 11, a target 62 facing substrate 11, a power supply unit 63 applying voltage between positive electrode 61 and target 62, a heating unit 64, and a control unit 65.

Heating unit 64 serves as a device for emitting argon gas at a predetermined temperature in the upward direction to blow the argon gas onto the lower surface of substrate 11. The temperature of the argon gas may be controlled to allow the temperature of substrate 11 to be at least 200° C. and lower than 300° C.

In this embodiment, the following function and effect are achieved according to the method of manufacturing an interconnection structure applied to a semiconductor device.

According to this embodiment, the TiN layer is formed in the process of forming the barrier metal layer with the temperature of substrate 11 maintained to be at least 200° C. and lower than 300° C.

The crystal structure is accordingly changed. Then, the orientation of the TiN crystal is changed from that in an amorphous state to (111) orientation. With this change of the crystal structure, the coefficient of linear expansion of barrier metal layer 43 approaches the coefficient of linear expansion of Si which constitutes substrate 11. Consequently, residual stress in the deposited barrier metal layer 43 can be reduced.

Moreover, the temperature of substrate 11 which is kept lower than 300° C. can prevent, if such a low-melting material as aluminum is used for conductive layer 44, bulge of the aluminum from occurring.

According to this embodiment, in the process of forming the barrier metal layer, the temperature of substrate 11 is kept in the above-mentioned range by blowing a high-temperature gas onto the lower surface of substrate 11. Uniform heating is thus accomplished.

According to this embodiment, the above-discussed structure can reduce the residual stress in the deposited barrier metal layer 43 to improve adhesiveness between interlayer insulating film 41 and barrier metal layer 43. Consequently, peeling can be suppressed that occurs at the interface between barrier metal layer 43 and interlayer insulating film 41 in such a polishing process as CMP.

According to this embodiment, in the process of forming the barrier metal layer, TiN/Ti is deposited through the directional bias sputtering only. Alternatively, another method, CVD for example, may be applied to form the TiN layer with the temperature of substrate 11 maintained to be at least 200° C. and lower than 300° C. in order to achieve the effect of reducing the residual stress in barrier metal layer 43.

Moreover, according to this embodiment, the high-temperature gas is blown to substrate 11 for heating the substrate and keeping the temperature thereof. Alternatively, the substrate may be heated by being adhered to an electrostatic chuck. In this case, substrate 11 can be heated uniformly.

Second Embodiment

A second embodiment is now described with respect to only differences between the first and second embodiments.

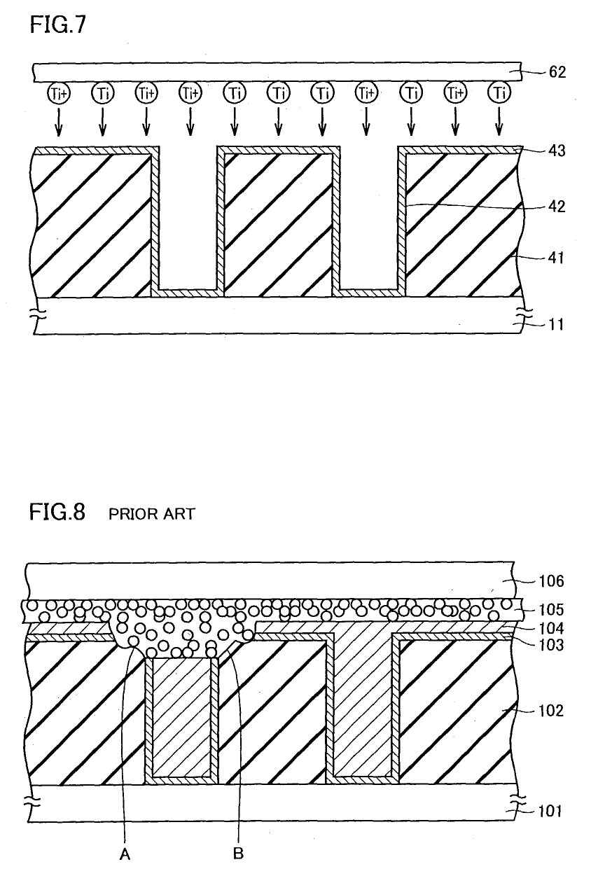

According to this embodiment, the directional bias sputtering is used in the process of forming a barrier metal layer. In the directional bias sputtering, partially ionized Ti sputtering particles are emitted from Ti target 62 as shown in FIG. 7 to deposit a TiN/Ti layer on an interlayer insulating film 41. The bias power at this time is set to be at least 50 W and at most 100 W.

A sputtering apparatus used for this embodiment includes a control unit 65 as shown in FIG. 6. Control unit 65 controls the bias power applied from a power supply unit 63 to the region between a positive electrode 61 and target 62. Control unit 65 keeps the bias power of 100 W or lower. This sputtering apparatus can suppress increase of spacing between atoms in the lattice that constitute the completed barrier metal layer, and accordingly reduce residual stress resulting from compression in the deposited barrier metal layer.

According to this embodiment, the bias power for the directional bias sputtering is 100 W or lower in the process of forming the barrier metal layer. Thus, the number of argon atoms implanted into barrier metal layer 43 in the process of bias sputtering can be decreased. It is accordingly possible to suppress increase of spacing between atoms in the lattice that constitute barrier metal layer 43 and reduce residual stress due to compression occurring in the deposited barrier metal layer 43.

Moreover, according to this embodiment, the bias power for the directional bias sputtering is at least 50 W in the process of forming the barrier metal layer. Although decreased bias power generally deteriorates the coverage due to lowered directivity of sputtering particles, the bias power of at least 50 W can keep such an influence within an acceptable range.

Consequently, the residual stress in the deposited barrier metal layer 43 can be reduced to enhance the adhesiveness between barrier metal layer 43 and interlayer insulating film 41. Thus, in such a polishing process as CMP, peeling can be suppressed that occurs at the interface between barrier metal layer 43 and interlayer insulating film 41.

According to this embodiment, the bias power in the process of forming the barrier metal layer is at least 50 W. However, if the requirement for coverage of barrier metal layer 43 for the bottom of the interconnection recess is less severe, the bias power may be smaller than 50 W. In this case, further decrease is possible of the number of argon atoms implanted into the barrier metal layer in the sputtering process.

The above-discussed first and second embodiments may be combined. Specifically, the TiN layer may be formed in the process of forming the barrier metal layer with the temperature of substrate 11 maintained to be at least 200° C. and with the bias power for the directional bias sputtering kept at 100 W or less. In this way, the residual stress in the deposited barrier metal layer 43 can further be reduced.

Referring to FIG. 1, a semiconductor device is described that is manufactured through the method, applied to the semiconductor device, of manufacturing an interconnection structure as detailed above. The semiconductor device includes interlayer insulating films 12 and 13 formed on substrate 11 and conductive plugs 21 and 33 as well as damascene interconnection 25 formed in the films, and further includes barrier metal layers 23, 27 and 35 provided on the inside surfaces respectively of interconnection recesses 22, 26 and 34 in interlayer insulating films 12 and 13, and conductive layers 24, 28 and 36 filing the interconnection recesses 22, 26 and 34. In barrier metal layers 23, 27 and 35 of the semiconductor device to which the manufacturing methods of the first and second embodiments are applied, residual stress is 3.0×10⁹ Pa or lower.

According to experiments conducted by the inventors of the present invention, if the residual stress in barrier metal layers 23, 27 and 35 is 3.0×10⁹ Pa or less, peeling which occurs at the interfaces between barrier metal layers 23, 27 and 35 and interlayer insulating films 12 and 13 can be reduced to a remarkable degree in such a polishing process as CMP.

According to the method of manufacturing an interconnection structure applied to a semiconductor device of the present invention, the residual stress in the deposited barrier metal layer can effectively be reduced. Thus, the adhesiveness between the barrier metal layer and the interlayer insulating film can be enhanced to suppress peeling occurring at the interface between the barrier metal layer and the interlayer insulating film in the polishing process.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing an interconnection structure applied to a semiconductor device including an interlayer insulating film formed on a substrate as well as a conductive plug and a damascene interconnection formed in said interlayer insulating film, comprising the steps of:
forming a barrier metal layer constituted of a Ti layer and a TiN layer on a surface of said interlayer insulating film and on an inside surface of an interconnection recess formed in said interlayer insulating film;
forming a conductive layer to fill said interconnection recess; and
polishing to remove a deposited extra part of said conductive layer,
said substrate having a temperature maintained to be at least 200° C. and lower than 300° C. for forming said TiN layer in said step of forming said barrier metal layer.

2. The method of manufacturing an interconnection structure according to claim 1, wherein
said TiN layer is formed by sputtering in said step of forming said barrier metal layer.

3. The method of manufacturing an interconnection structure according to claim 1, wherein
gas at a predetermined temperature is blown onto a back surface of said substrate to maintain said substrate to be at least 200° C. and lower than 300° C. for forming said TiN layer in said step of forming said barrier metal layer.

4. A method of manufacturing an interconnection structure applied to a semiconductor device including an interlayer insulating film formed on a substrate as well as a conductive plug and a damascene interconnection formed in said interlayer insulating film, comprising the steps of:
forming a barrier metal layer on a surface of said interlayer insulating film and on an inside surface of an interconnection recess formed in said interlayer insulating film;
forming a conductive layer to fill said interconnection recess; and
polishing to remove a deposited extra part of said conductive layer,
bias sputtering being carried out in said step of forming said barrier metal layer with bias power for said bias sputtering being at most 100 W.

5. The method of manufacturing an interconnection structure according to claim 4, wherein
said bias power is at least 50 W.
